(19) United States
(12) Patent Application Publication
(10) Pub. No.: US 2012/0156843 A1
(43) Pub. Date: Jun. 21, 2012

(54) DIELECTRIC LAYER FOR GALLIUM NITRIDE TRANSISTOR

(76) Inventors: Bruce M. Green, Gilbert, AZ (US); Darrell G. Hill, Tempe, AZ (US); Karen E. Moore, Phoenix, AZ (US)

(21) Appl. No.: 12/971,165

(22) Filed: Dec. 17, 2010

(51) Int. Cl. H01L 21/336

(52) U.S. Cl. 438/261; 257/E21.441

(57) ABSTRACT

A dielectric layer for a gallium nitride transistor is disclosed. In one example, the dielectric layer has a hydrogen content of less than or equal to 10% by atomic percentage. In one example, both a dielectric layer formed before a conductive electrode of the transistor and a dielectric layer formed after the conductive elective electrode have a hydrogen content of less than or equal to 10% by atomic percentage. In one example, the dielectric layer formed before the conductive electrode is formed by a LPCVD process and the dielectric layer formed after the conductive electrode is formed by a sputtering process.

### BACKGROUND OF THE INVENTION

1. Field of the Invention

This invention relates in general to gallium nitride transistors and in particular to dielectric layers for gallium nitride transistors.

2. Description of the Related Art

Gallium nitride transistors are transistors that utilize a gallium nitride material. Gallium nitride transistors can be used, for example, in radio frequency power amplifiers, power switches for DC converters (e.g. for electric cars and power supplies), and in microwave ovens. A gallium nitride material is a material that includes a gallium nitride compound such as gallium nitride, aluminum gallium nitride, or indium gallium nitride. A gallium nitride material may also be doped with other atoms or ions such as oxygen, silicon, germanium, carbon, iron, or magnesium.

### BRIEF DESCRIPTION OF THE DRAWINGS

The present invention may be better understood, and its numerous objects, features, and advantages made apparent to those skilled in the art by referencing the accompanying drawings.

FIGS. 1-7 are partial cross-sectional side views of a gallium nitride transistor at various stages in its manufacture according to one embodiment of the present invention.

FIG. 8 is a partial cross sectional side view of a gallium nitride transistor at a stage in its manufacture according to another embodiment of the present invention.

The use of the same reference symbols in different drawings indicates identical items unless otherwise noted. The Figures are not necessarily drawn to scale.

### DETAILED DESCRIPTION

The following sets forth a detailed description of a mode for carrying out the invention. The description is intended to be illustrative of the invention and should not be taken to be limiting.

It has been discovered that a providing a gallium nitride transistor with one or more dielectric layers having a low hydrogen content may advantageously lead to better performance of the transistor. For example, with gallium nitride transistors, it has been discovered that a low hydrogen dielectric layer can minimize the migration of hydrogen into the interface of the conductive electrode/gallium nitride material. Minimizing the amount of hydrogen migrating into the interface may reduce the gate leakage current of a gallium nitride transistor. It is believed that the hydrogen at the interface reduces the barrier to electron flow wherein electrons tunnel more easily through the gallium nitride material.

In addition, it has been discovered that migrating hydrogen not only comes from lower level dielectric layers but also from dielectric layers applied after the formation of the conductive electrodes. Accordingly, providing a gallium nitride transistor with a dielectric layer of a low hydrogen content (less than or equal to 10% hydrogen by atomic percentage), may provide for a gallium nitride transistor with a lower leakage current. In some embodiments, it is even preferable that the hydrogen content be even lower (less than or equal to 5% hydrogen by atomic percentage).

FIGS. 1-7 set forth partial cross sectional side views of a wafer at various stages of manufacture of a gallium nitride transistor. Wafer 101 includes a substrate layer 103 of a material such as e.g. silicon, quartz, sapphire, silicon carbide, gallium nitride, or aluminum nitride. Layer 105 is a layer of a gallium nitride material which includes a gallium nitride compound. In one embodiment, the gallium nitride compound is GaN, but may be of other gallium nitride compounds such as e.g. AlGaN or InGaN in other embodiments. The gallium nitride material of layer 105 may be doped impurities such as e.g. oxygen, silicon, carbon, or manganese, or may be undoped.

A layer 106 is formed on layer 105. Layer 106 includes a material that has a different band gap than that of layer 105 to implement a hetero structure junction between two materials with different band gaps for forming a hetero structure field effect transistor (HFET) (also known as a high electron mobility transistor (HEMT)). In one embodiment, layer 105 is made of GaN and layer 106 is made of AlGaN or InGaN. However, layers 105 and 106 may be made of other materials to implement layers having different band gaps. The hetero junction serves as a channel for the HFET.

In one embodiment, layer 106 is formed by a chemical deposition process, but may formed by other processes in other embodiments. In one embodiment, layer 106 would be formed on wafer 101 in the same deposition chamber as where layer 105 is formed but with the use of an additional precursor. In one embodiment, layer 106 has a thickness of 50-300 Angstroms (A), but may be of other thicknesses is in other embodiments.

In some embodiments, wafer 101 includes a cap layer (not shown) located on layer 106. In one embodiment where layer 106 includes aluminum gallium nitride, the cap layer includes gallium nitride. In one embodiment, the cap layer is 30 A thick, but may range between 5-100 A in other embodiments.

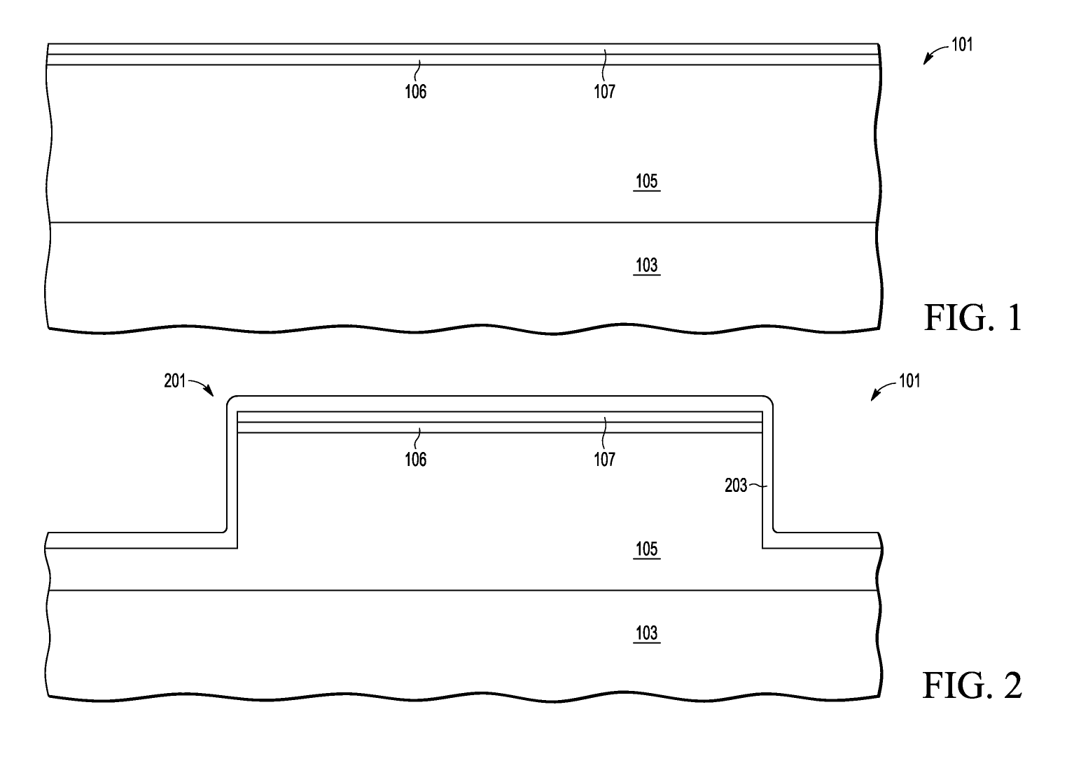

Layer 107 is a dielectric layer that is formed over layer 106. In one embodiment, layer 107 is made of silicon nitride e.g. Si₃N₄, but may be made of other silicon nitride materials or other dielectric materials. Layer 107 is used to passivate layers 105 and 106 and to protect the top surface of layer 106 (or a capping layer) during a subsequent selective etching of that layer. See FIG. 2. In one embodiment, layer 107 is 200-2000 A thick but may have other thicknesses in other embodiments.

Layer 107 is deposited to have a low hydrogen content. In one embodiment, layer 107 is formed by a low pressure chemical vapor deposition process (LPCVD) where the deposition conditions are set such that layer 107 has a low hydrogen content. Also in some embodiments, the conditions are set such that layer 107 has a high dielectric breakdown strength (greater than or equal to 0.5 mega volts per centimeter and more preferably greater than or equal to 1 mega volt per centimeter). Providing a dielectric layer with a high dielectric breakdown strength may inhibit breakdown and ionization of the dielectric layer at regions around the gate. In some embodiments, a high electric field on the gallium nitride material can ionize materials at the surface near the gate, producing a negative charge that can act as a “virtual gate” during operation. By using dielectrics with a high dielectric breakdown strength, dielectric breakdown may be inhibited and current collapse may be reduced.

Also in some embodiments, the deposition conditions are set such that layer 107 has a low porosity which is indicated by a low wet etch rate. For silicon nitride, a low wet etch is a wet etch rate of less than or equal to 2 A per second in a 6:1 buffered oxide etchant. A 6:1 buffered oxide etchant is an etchant that is 6 parts aqueous ammonium fluoride and 1 part hydrofluoric acid, by volume. Aqueous ammonium fluoride is ammonium fluoride dissolved in water at a concentration of 40%, by weight. Hydrofluoric acid is pure HF combined with water to achieve a concentration of 49% HF, by weight. However, in some embodiments a wet etch rate of less than or equal to 1 A per second is even more preferable. Providing a dielectric layer with a low porosity improves the breakdown field strength of the dielectric layer.

In one embodiment, layer 107 is deposited with a deposition temperature of 740 C. Also, the maximum deposition pressure is 200 mTorr. In one embodiment, the deposition of the silicon nitride occurs in the presence of N2 gas, NH3 gas, and dichlorosilane gas with flow rates of 20 sccm, 150 sccm, and 80 sccm, respectively for 30 minutes, although the silicon nitride layer may be formed with other LPCVD process conditions in other embodiments. Also, in other embodiments, layer 107 may be formed by other materials and/or processes (e.g. sputtering) to provide a low hydrogen content.

The relative high deposition temperature (650 C or greater) of the deposition process provides for a better reaction of the dichlorosilane and NH3 to produce a more uniform silicon nitride, which is more dense and has a lower hydrogen content.

FIG. 2 is a partial cross sectional view of wafer 101 after layer 105, layer 106, and layer 107 have been patterned to form a mesa 201 and another dielectric layer 203 is formed over wafer 101. In one embodiment, mesa 201 is formed by forming a corresponding photolithographic mask over wafer 101 and etching layers 105, 106, and 107 with appropriate etch chemistries. In the embodiment shown, layer 105 is etched for a timed amount to a particular depth. However in other embodiments, layer 105 may be etched to layer 103. In one embodiment, mesa 201 has a height of 1000 to 5000 A, but may have other heights in other embodiments.

Layer 203 is formed on layer 107 and on the sidewalls of mesa 201. Layer 203 has a low hydrogen content and in some embodiments, a low porosity and a high dielectric breakdown strength. In one embodiment, layer 203 is made of the same material (e.g. silicon nitride) and formed by the same processes as layer 107. However, layer 203 may be formed by other processes or be made of other materials in other embodiments. In one embodiment, layer 203 is 200-2000 A thick, but may be of other thicknesses in other embodiments. Providing layer 203 with a low hydrogen content, a high dielectric breakdown strength, and a low porosity may provide advantages similar to those stated up above with respect to layer 107 for the same characteristics.

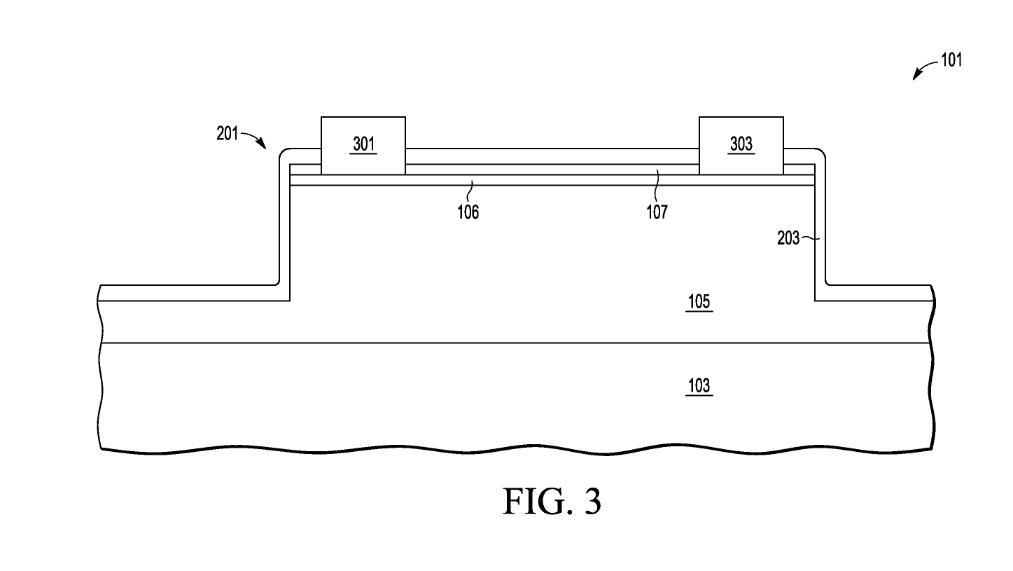

FIG. 3 is a partial side view of wafer 101 after source electrode 301 and drain electrode 303 are formed on wafer 101. In one embodiment, layers 203 and 107 are selectively etched to form openings to expose layer 106 (or the capped layer in some embodiments) wherein electrodes 301 and 303 are formed in the openings. In some embodiments, electrodes 301 and 303 are in ohmic contact with layer 106 (or the cap layer in some embodiments.) In some embodiments, electrodes 301 and 303 may be made of multiple layers of different materials such as titanium, aluminum, molybdenum, nickel, and gold e.g. having a layered configuration of Ti/Al/Mo/Au, Ti/Al/Ni/Au, or Ti/AI (with titanium contacting layer 106.) In one embodiment, the conductive material is deposited on the patterned photo resist (not shown) formed over wafer 101 that is used for etching the openings in layers 203 and 107. The conductive material is deposited using evaporation or other suitable processes. After deposition, the photo resist is dissolved in solvent, leaving the formed electrodes 301 and 303 and “lifting off” metal not used to form electrodes 301 and 303. In other embodiments, the electrodes 301 and 303 are formed by depositing the conductive metal over the wafer 101 and then patterning by chemical etching.

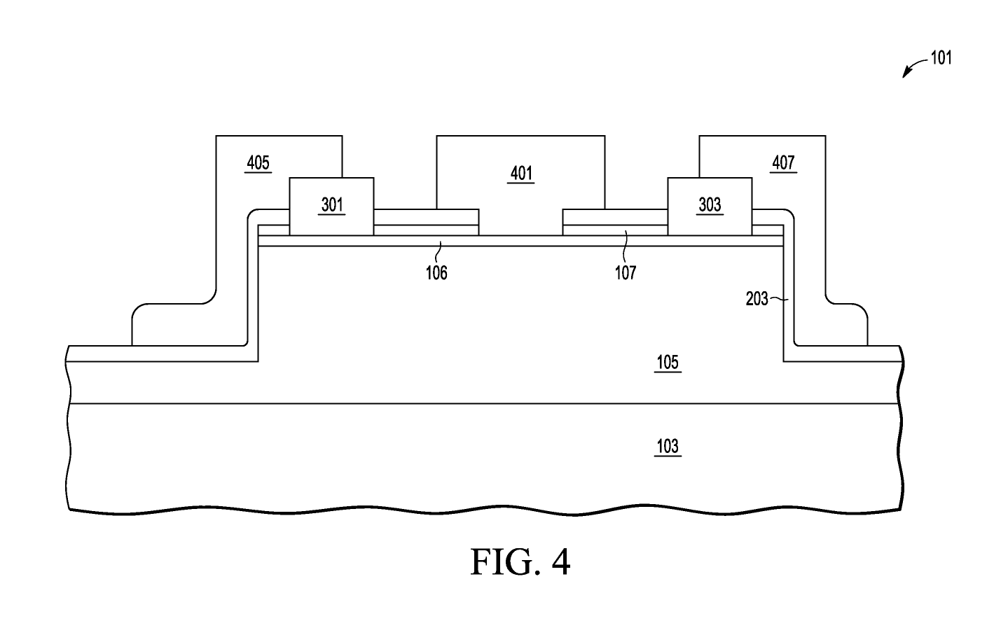

FIG. 4 shows wafer 101 after the formation of a gate electrode 401 and conductive interconnects 405 and 407. In one embodiment, gate electrode 401 is formed by forming an opening in layers 107 and 203 to expose layer 106 (or the capping layer in some embodiments). The patterned photo resist layer (not shown) used to form the openings in dielectric layers 107 and 203 is removed after their formation. A second photo resist layer (not shown) is then formed over wafer 101. This second photo resist layer is patterned to form openings for interconnects 405 and 407 and an opening for gate electrode 401. The opening in the second photo resist layer for gate electrode 401 is wider than the openings in layers 107 and 203 at that location. The conductive layer or layers are formed on the patterned second photo resist layer and in its openings. The second patterned photo resist layer is then dissolved to leave gate electrode 401 and interconnects 405 and 407, wherein all other conductive material is lifted off.

In one embodiment, gate electrode 401 is in Schottky contact with layer 106 (or the capping layer). In one embodiment, electrode 401 is composed of multiple layers of different materials. For example, the bottom layer of electrode 401 is formed of nickel, platinum, or other high work function metals e.g. such as palladium, rhenium, iridium, to make Schottky contact with the gallium nitride material. A conductive material e.g. gold is formed over the high work function metal layers. In other embodiments, interconnects 405 and 407 may be formed separately. In one embodiment, gate electrode 401 is 1000-20000 A thick, but may be of other thicknesses in other embodiments.

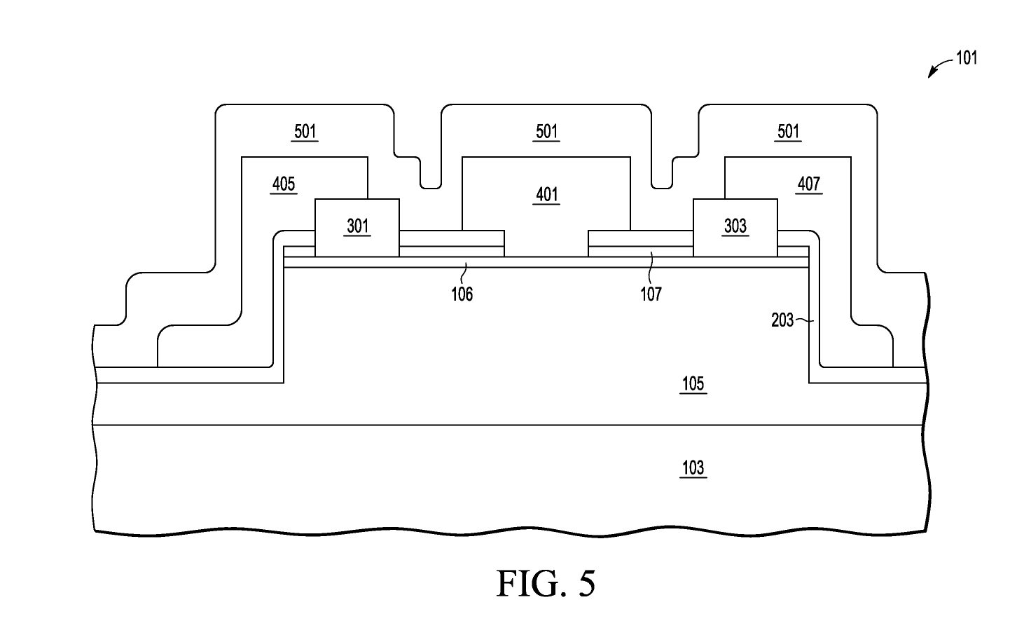

FIG. 5 shows a view of wafer 101 after dielectric layer 501 is formed over wafer 101. Dielectric layer 501 has a low hydrogen content to limit the amount of hydrogen that migrates to the gate electrode/gallium nitride material interface. In one embodiment, layer 501 is made of silicon nitride formed by a sputtering process, but may be made of other dielectric materials and/or other processes in other embodiments. For example, layer 501 may be made of aluminum nitride, silicon oxide, silicon oxynitride, or silicon dioxide. In one embodiment, layer 501 has a thickness of 100-20000 A but may have other thickness in other embodiments.

In one embodiment, layer 501 is formed by a sputtering process to provide for a low hydrogen content layer. In some embodiments, a LPCVD process is not used because the relatively high temperatures of the process would impair the Schottky and ohmic properties of the conductive electrodes (electrodes 301 and 303 and gate electrode 401). Accordingly, using a sputtering process allows for layer 501 to be of a low hydrogen content. Also in some embodiments, the sputtering process allows for layer 501 to have a low porosity (as indicated by a low etch rate) to provide high breakdown field strength. Providing a dielectric layer with a low hydrogen content that is formed after the electrodes acts to reduce the amount of hydrogen from that layer that migrates to the gate electrode/gallium nitride material interface. Also, providing a layer with a high dielectric breakdown strength may help prevent current collapse.

In one embodiment, layer 501 is made of a silicon nitride material and is formed by a sputtering process where the RF power is 2 KW, the pressure is 12 mTorr, the argon flow rate is 57 sccm, and the nitrogen flow rate is 54 sccm. However, layer 501 may be formed with different sputtering parameters in other embodiments. In some embodiments it is desirable that the mass ratio of the amount of nitrogen to argon be at least 0.5 and more preferably, greater than or equal to 0.9. It is believed that providing a sputtering process to form silicon nitride where the nitrogen to argon mass ratio is greater than 0.5 may provide for a lower porosity, lower etch rate, and higher breakdown field strength film. In some embodiments, it is desirable to sputter silicon nitride with the sputtering process being operated in a “poisoned” mode. With a sputtering process in a poisoned mode, a silicon nitride film forms on a silicon target of a sputtering chamber. Particles of the silicon nitride material are then sputtered off of the target and redeposited on the wafer to form the dielectric layer. It is believed that forming a dielectric layer by a sputtering process in such a poisoned mode provides for a stable process that produces a dielectric layer that has a low etch rate.

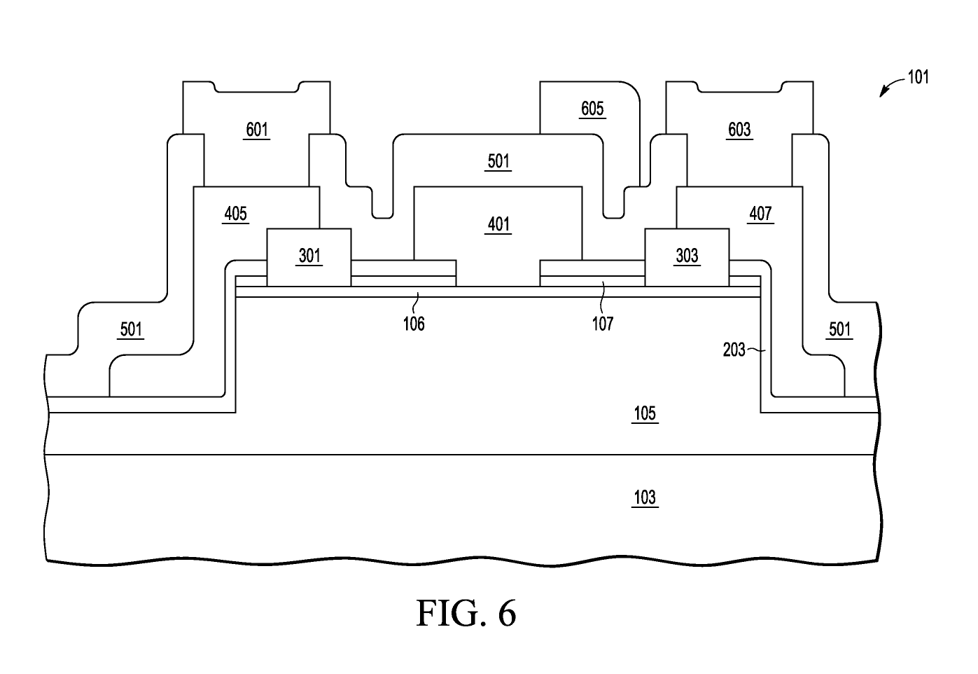

FIG. 6 is a view of wafer 101 after contacts 601 and 603 and field plate 605 are formed on wafer 101. In one embodiment, openings are formed in layer 501 to exposed interconnects 405 and 407. A layer of conductive material is deposited and patterned on wafer 101 to form contacts 601 and 603. In one embodiment, contacts 601 and 603 are formed of a metal such as gold or aluminum, however, they may be made of other materials. In some embodiments, contacts 601 and 603 may be made of multiple materials. For example, contacts 601 and 603 may include diffusion barrier layers.

Field plate 605 is formed of a conductive material. In some embodiments, it may be formed of the same material as contacts 603 and 601, but may be formed of other materials and/or at other times in other embodiments. A field plate shields the transistor gate from the transistor drain, lowering the associated gate-drain capacitance thereby making the transistor have improved stability and higher gain. Transistors of other embodiments may not include a field plate.

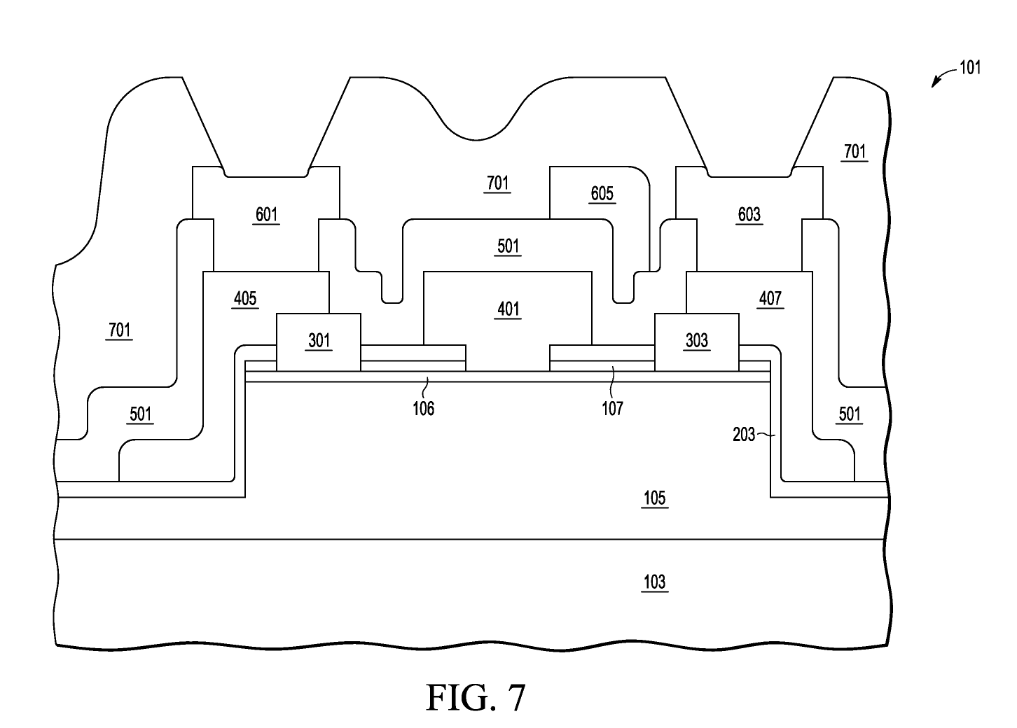

FIG. 7 shows wafer 101 after another dielectric layer 701 is formed over wafer 101 and patterned to form openings to expose contacts 601 and 603. Dielectric layer 701 has a low hydrogen content to limit the amount of hydrogen migrating to the electrode/gallium nitride material interface. In some embodiments, layer 701 has a high dielectric breakdown strength and a low porosity. In one embodiment, layer 701 is formed by a sputtering process and is made of silicon nitride, although layer 701 may be formed by other processes and/or made of other dielectric materials in other embodiments. In one embodiment, layer 701 is formed by the same sputtering process as layer 501. In one embodiment, layer 701 is 200-20000 A thick, but may be of other thicknesses in other embodiments.

As shown in FIG. 7, a gallium nitride HFET device is formed with a source electrode 301, a drain electrode 303, and gate electrode 401. The junction between layers 106 and 105 serves as the hetero junction. Not shown in FIG. 7 is an electrical connection to gate electrode 401 that occurs outside of the view of FIG. 7. Wafer 101 includes multiple HFET devices similar to the one shown in FIG. 7.

After the stage of FIG. 7, other processes may be performed on wafer 101. For example, other conductive structures (not shown) may be formed on conductive contacts 601 and 603 for providing external connection of the transistor shown in FIG. 7. In other embodiments, other dielectric layers may be added for additional functions such as a capacitor dielectric or scratch and moisture protection. In some embodiments, it may be desirable that these other dielectric layers have a low hydrogen content. It may also be desirable that these other dielectric layers have a low porosity and high dielectric field strength. Also in some embodiments, the wafer may be planarized at various levels.

Afterwards wafer 101 is singulated into multiple chips where each chip includes at least one HFET. In some embodiments, the singulated chip includes only one gallium nitride transistor (the HFET). However in other embodiments, a chip may include multiple gallium nitride transistors and/or other devices and circuits.

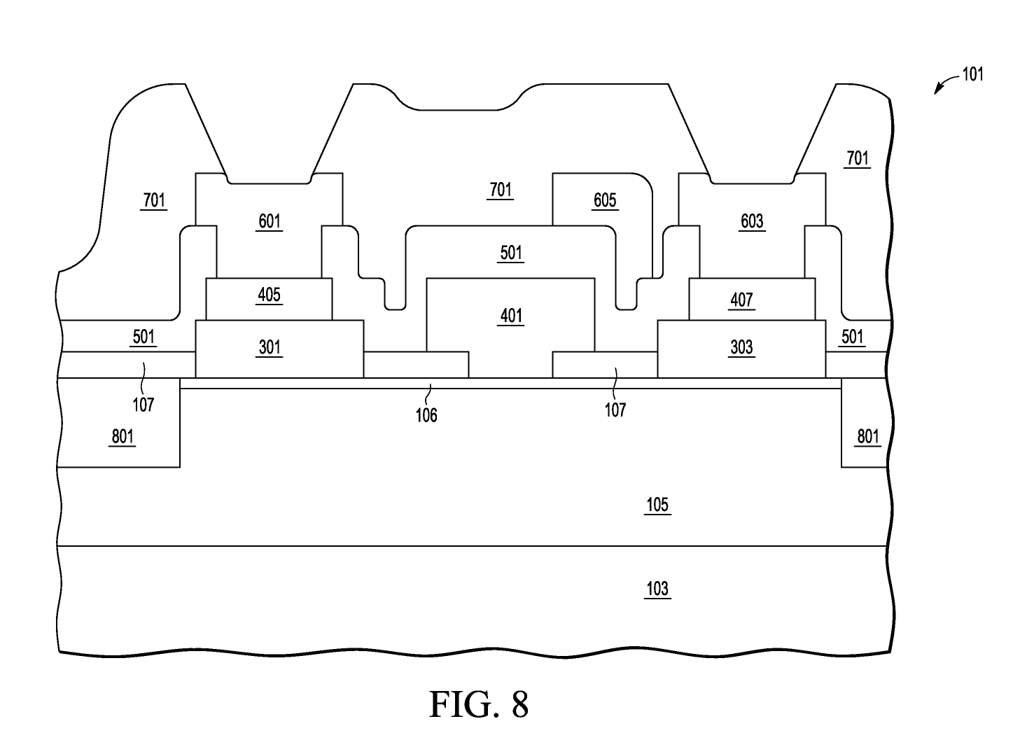

FIG. 8 shows another embodiment of a gallium nitride transistor according to the present invention. The transistor of FIG. 8 is similar to the transistor of FIG. 7 except that no mesa of layers 106 and 105 is formed. Instead, isolation region 801 is formed to surround the portion of layers 105 and 106 for the transistor of FIG. 8. In one embodiment, isolated region 801 is formed by implanting a species of atoms e.g. nitrogen into region 801 to an approximate depth of 1000-10000 A. Also with the embodiment of FIG. 8, because no mesa is formed, dielectric layer 203 is not needed.

In other embodiments, other types of gallium nitride transistors, e.g. a double hetero junction field effect transistor, may be implemented with dielectric layers similar to those described above.

In one embodiment, a method for forming a gallium nitride transistor includes forming a first dielectric layer over a gallium nitride material. The first dielectric layer has a hydrogen content of less than or equal to 10% by atomic percentage. The method includes forming a conductive electrode structure of the gallium nitride transistor over the gallium nitride material after the forming the first dielectric layer. The gallium nitride transistor includes a structure in the gallium nitride material. The method includes forming a second dielectric layer after the forming the conductive electrode structure. The second dielectric layer has a hydrogen content of less than or equal to 10% by atomic percentage.

In another embodiment, a method for forming a gallium nitride transistor includes forming by a low pressure chemical vapor deposition process a first dielectric layer over a gallium nitride material. A minimum deposition temperature of the low pressure chemical vapor deposition process is 650 C or greater. The method includes forming a conductive electrode structure of the gallium nitride transistor over the gallium nitride material after the forming the first dielectric layer. The gallium nitride transistor includes a structure in the gallium nitride material. The method includes forming a second dielectric layer by a sputtering process after forming the conductive electrode structure.

In another embodiment, a method for forming a gallium nitride transistor includes forming a first dielectric layer including silicon nitride over a gallium nitride material. The first dielectric layer has a hydrogen content of less than or equal to 10% by atomic percentage. The method includes forming a gate conductive electrode structure of the gallium nitride transistor over the gallium nitride material after the forming the first dielectric layer. The gallium nitride transistor includes a structure in the gallium nitride material. The method includes forming a source conductive electrode structure of the gallium nitride transistor over the gallium nitride material after the forming the first dielectric layer and forming a drain conductive electrode structure of the gallium nitride transistor over the gallium nitride material after the forming the first dielectric layer. The method includes forming a second dielectric layer after the forming the gate conductive electrode structure, the source conductive electrode structure, and the drain conductive electrode structure. The second dielectric layer has a hydrogen content of less than or equal to 10% by atomic percentage. The method includes forming a third dielectric layer after the forming the second dielectric layer. The third dielectric layer has a hydrogen content of less than or equal to 10% by atomic percentage.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A method for forming a gallium nitride transistor comprising:
forming a first dielectric layer over a gallium nitride material, the first dielectric layer having a hydrogen content of less than or equal to 10% by atomic percentage;
forming a conductive electrode structure of the gallium nitride transistor over the gallium nitride material after the forming the first dielectric layer, the gallium nitride transistor including a structure in the gallium nitride material;
forming a second dielectric layer after the forming the conductive electrode structure, the second dielectric layer having a hydrogen content of less than or equal to 10% by atomic percentage.

2. The method of claim 1, wherein forming the first dielectric layer includes forming the first dielectric layer to include silicon nitride by a low pressure chemical vapor deposition (LPCVD) process with a minimum chamber deposition temperature of at least 650 C.

3. The method of claim 1, wherein:
the first dielectric layer has a hydrogen content of less than or equal to 5% by atomic percentage;
the second dielectric layer has a hydrogen content of less than or equal to 5% by atomic percentage.

4. The method of claim 1, wherein forming the first dielectric layer includes forming the first dielectric layer to include silicon nitride by a low pressure chemical vapor deposition (LPCVD) process with a maximum chamber deposition pressure of 500 mTorr or less.

5. The method of claim 1, wherein forming the second dielectric layer includes forming the second dielectric layer by a sputtering process.

6. The method of claim 5 wherein the second dielectric layer includes silicon nitride.

7. The method of claim 6 wherein forming the second dielectric layer includes forming the second dielectric layer by a sputtering process in a poisoned mode.

8. The method of claim 5 wherein the forming the second dielectric layer includes sputtering silicon nitride in the presence of a nitrogen bearing gas and an argon bearing gas wherein the mass ratio of nitrogen to argon is at least 0.5.

9. The method of claim 1 further comprising:
forming a third dielectric layer over the second dielectric layer, wherein the third dielectric layer has a hydrogen content less than or equal to 10% by atomic percentage.

10. The method of claim 1 further comprising:
forming a drain electrode over the gallium nitride material;
forming a source electrode over the gallium nitride material;
forming a first opening in the second dielectric layer for forming a first electrically conductive structure to be electrically coupled to the drain electrode;
forming a second opening in the second dielectric layer for forming a second electrically conductive structure to be electrically coupled to the source electrode;
wherein the conductive electrode structure is a gate electrode structure.

11. The method of claim 1 further comprising:
forming a semiconductor layer over the gallium nitride material, the semiconductor layer having a band gap different than that of the gallium nitride material, wherein the first dielectric layer is formed over the semiconductor layer.

12. The method of claim 1 further comprising:
after forming the first dielectric layer, patterning the first dielectric layer and the gallium nitride material to form a mesa;
forming a third dielectric layer over the first dielectric layer, wherein the third dielectric layer is formed on sidewalls of the mesa, the third dielectric layer having a hydrogen content of less than or equal to 10% by atomic percentage;
wherein the conductive electrode is formed after the forming the third dielectric layer.

13. The method of claim 1 wherein the first dielectric layer and the second dielectric layer each have a buffered oxide wet etch rate in a 6:1 buffered oxide etchant of 2 A per second or less.

14. The method of claim 1 wherein the first dielectric layer and the second dielectric layer each have a dielectric breakdown strength of 0.5 Mega Volts/cm or greater.

15. A method for forming a gallium nitride transistor comprising:
forming by a low pressure chemical vapor deposition process a first dielectric layer over a gallium nitride material, wherein a minimum deposition temperature of the low pressure chemical vapor deposition process is 650 C or greater;
forming a conductive electrode structure of the gallium nitride transistor over the gallium nitride material after the forming the first dielectric layer, the gallium nitride transistor including a structure in the gallium nitride material;
forming a second dielectric layer by a sputtering process after forming the conductive electrode structure;
wherein the first dielectric layer and the second dielectric layer each have a hydrogen content by atomic percentage of less than or equal to 10%.

16. The method of claim 15 wherein the forming the second dielectric layer includes sputtering silicon nitride in the presence of a nitrogen bearing gas and an argon bearing gas wherein the mass ratio of nitrogen to argon is at least 0.5.

17. The method of claim 15 wherein the first dielectric layer and the second dielectric layer each have a wet etch rate in a 6:1 buffered oxide etchant of 2 A per second or less.

18. The method of claim 15 wherein the sputtering process is performed in a poisoned mode.

19. (canceled)

20. A method for forming a gallium nitride transistor comprising:
forming a first dielectric layer including silicon nitride over a gallium nitride material, the first dielectric layer having a hydrogen content of less than or equal to 10% by atomic percentage;
forming a gate conductive electrode structure of the gallium nitride transistor over the gallium nitride material after the forming the first dielectric layer, the gallium nitride transistor including a structure in the gallium nitride material;
forming a source conductive electrode structure of the gallium nitride transistor over the gallium nitride material after the forming the first dielectric layer;
forming a drain conductive electrode structure of the gallium nitride transistor over the gallium nitride material after the forming the first dielectric layer;
forming a second dielectric layer after the forming the gate conductive electrode structure, the source conductive electrode structure, and the drain conductive electrode structure, the second dielectric layer having a hydrogen content of less than or equal to 10% by atomic percentage;
forming a third dielectric layer after the forming the second dielectric layer, the third dielectric layer having a hydrogen content of less than or equal to 10% by atomic percentage.

21. The method of claim 1 wherein the first dielectric layer includes silicon nitride and the second dielectric layer includes silicon nitride.
